(19) United States
(12) Patent Application Publication
(10) Pub. No.: US 2024/0222395 A1
(43) Pub. Date: Jul. 4, 2024

(54) BACKSIDE-CONNECTING VIA WITH NANOSHEET SPACERS FOR TRANSISTORS

(71) Applicant: INTERNATIONAL BUSINESS MACHINES CORPORATION, ARMONK, NY (US)

(72) Inventors: Oscar van der Straten, Guilderland Center, NY (US); Tsung-Sheng Kang, Ballston Lake, NY (US); Alexander Reznicek, Troy, NY (US); Koichi Motoyama, Clifton Park, NY (US)

(21) Appl. No.: 18/091,968

(22) Filed: Dec. 30, 2022

(51) Int. Cl. H01L 27/12

(52) U.S. Cl. CPC H01L 27/1248; H01L 27/124; H01L 27/1266

(57) ABSTRACT

Embodiments are disclosed for a semiconductor device array and a method for fabricating the semiconductor device array. The semiconductor device array includes a backside power distribution network (BSPDN), a buried power rail (BPR) in electrical contact with the BSPDN, a device layer, and a backside-connecting via. The device layer includes a first transistor, a second transistor, a first spacer, and a second spacer. Further, the first transistor is in electrical contact with the first spacer. Additionally, the second transistor is in electrical contact with the second spacer. Also, the first transistor neighbors the second transistor. Further, the backside-connecting via is in electrical contact with the first transistor, the BPR, the first spacer, and the second spacer.

### BACKGROUND

The present disclosure relates to transistors, and more specifically, to a backside-connecting via with nanosheet spacers for transistors.

Transistors are semiconductor devices that can switch electrical current in the form of signals and power. These traits make transistors, in large scales, useful for electronic devices, such as computer processors, memory, and the like. Transistors can include field effect transistors (FETs), such as nanosheet FETs, vertical transport FETs (VTFETs), or FinFETs; semiconductor memory structures, and the like. Further, transistors can be fabricated into integrated circuits having various elements that enable the transistors' operation. For example, a backside power distribution network (BSPDN) provides electrical current and logical connections. Additionally, buried power rails (BPRs) electrically connect the BSPDN to the transistors. More specifically, a backside-connecting via of the BSPDN electrically connects the BPRs with the transistors. The backside-connecting via is an interconnect structure. Current fabrication methods for backside interconnect structures such as, vias, involve forming a relatively deep trench between two transistors. Accordingly, the resulting via formed in the trench provides electrical connection between the buried power rail and the transistor.

However, the distance from the buried power rails to the top of the transistor is larger than the distance between adjacent transistors. As such, the aspect ratio of any via connecting X to Y is relatively high. The relatively high aspect ratio increases the likelihood of voids in the metal, which increases the resistance of the backside-connecting via; also, the contact area at the bottom of the connecting via is relatively small. Having a relatively small contact area can also increase resistance. Increased resistance is detrimental to the operation of the semiconductor device. Widening the opening of the trench may reduce the aspect ratio, thus reducing the incidence of voids, creating more via volume, and creating more contact area at the bottom surface connecting to the BPR. Further, reducing voids, increasing via volume, and increasing via contact area with the BPR can decrease via resistance. However, such widening may bring the backside-connecting via into electrical contact with a neighboring transistor. Such contact creates a short, which renders the semiconductor device inoperable.

### SUMMARY

Embodiments are disclosed for a semiconductor device including a backside power distribution network (BSPDN), a buried power rail (BPR) in electrical contact with the BSPDN, a device layer, and a backside-connecting via. The device layer includes a first transistor, a second transistor, a first spacer, and a second spacer. Further, the first transistor is in contact with the first spacer. Additionally, the second transistor is in contact with the second spacer. Also, the first transistor neighbors the second transistor. Further, the backside-connecting via is in contact with the BPR, the first spacer, and the second spacer. Additionally, the backside-connecting via is in electrical contact with the first transistor. Accordingly, such embodiments can provide a backside-connecting via with reduced resistance resulting from increased via volume and increased via contact area with the buried power rail. Additionally, such embodiments can increase the scalability of the BSPDN due to a larger process window for backside-connecting via metal fill. Additionally, such embodiments can improve the performance of the semiconductor device due to reduced resistance between the backside-connecting via and the transistors.

Embodiments are disclosed for a semiconductor device including a backside power distribution network (BSPDN), a buried power rail (BPR) in electrical contact with the BSPDN, a device layer, and a backside-connecting via. The device layer includes a first transistor, a second transistor, a first spacer, and a second spacer. Further, the first transistor is in contact with the first spacer. Additionally, the second transistor is in contact with the second spacer. Also, the first transistor neighbors the second transistor. Further, the backside-connecting via is in contact with the BPR, the first spacer, and the second spacer. Additionally, the backside-connecting via is in electrical contact with the first transistor. Further, the second spacer prevents a short resulting from electrical contact between the second transistor and the backside-connecting via. Additionally, the backside-connecting via is without metal voids. Accordingly, such embodiments can provide a backside-connecting via with reduced resistance resulting from a void free metal fill, increased via volume, and increased via contact area with the buried power rail. Additionally, such embodiments can increase the scalability of the BSPDN due to a larger process window for backside-connecting via metal fill. Additionally, such embodiments can improve the performance of the semiconductor device due to reduced resistance between the backside-connecting via and the transistors.

Embodiments are disclosed for a semiconductor device including a backside power distribution network (BSPDN), a buried power rail (BPR) in electrical contact with the BSPDN, a device layer, and a backside-connecting via. The device layer includes a first transistor, a second transistor, a first spacer, and a second spacer. Further, the first transistor is in contact with the first spacer. Additionally, the second transistor is in contact with the second spacer. Also, the first transistor neighbors the second transistor. Further, the backside-connecting via is in contact with the BPR, the first spacer, and the second spacer. Additionally, the backside-connecting via is in electrical contact with the first transistor. Further, the second spacer prevents a short resulting from electrical contact between the second transistor and the backside-connecting via. Additionally, the backside-connecting via is without metal voids. Further, the backside-connecting via includes a bottom in contact with the BPR. Additionally, the width of the bottom of the backside-connecting via is at least one half of the width of the top of the backside-connecting via. Accordingly, such embodiments can provide a backside-connecting via with reduced resistance resulting from a void free metal fill, increased via volume, and increased via contact area with the buried power rail. Additionally, such embodiments can increase the scalability of the BSPDN due to a larger process window for backside-connecting via metal fill. Additionally, such embodiments can improve the performance of the semiconductor device due to reduced resistance between the backside-connecting via and the transistors.

Embodiments are disclosed for a semiconductor device including a backside power distribution network (BSPDN), a buried power rail (BPR) in electrical contact with the BSPDN, a device layer, and a backside-connecting via. The device layer includes a first transistor, a second transistor, a first spacer, and a second spacer. Further, the first transistor is in contact with the first spacer. Additionally, the second transistor is in contact with the second spacer. Also, the first transistor neighbors the second transistor. Further, the backside-connecting via is in contact with the BPR, the first spacer, and the second spacer. Additionally, the backside-connecting via is in electrical contact with the first transistor. Further, the second spacer prevents a short resulting from electrical contact between the second transistor and the backside-connecting via. Additionally, the backside-connecting via is without metal voids. Further, the width of the portion of the backside-connecting via beneath the first spacer and the second spacer is wider than the width of the portion of the backside-connecting via between the first spacer and the second spacer. Accordingly, such embodiments can provide a backside-connecting via with reduced resistance resulting from eliminated voids, increased via volume, and increased via contact area with the buried power rail. Additionally, such embodiments can increase the scalability of the BSPDN due to a larger process window for backside-connecting via metal fill. Additionally, such embodiments can improve the performance of the semiconductor device connected to as BSPDN due to reduced resistance between the backside-connecting via and the transistors.

Embodiments are disclosed for a method for fabricating a semiconductor device. The method includes depositing a dielectric layer over a plurality of transistors. The method further includes performing a directional reactive ion etch-back of the dielectric layer to form a plurality of sidewall spacers that surround each of the transistors. Additionally, the method includes forming a backside-connecting via between two of the plurality of nanosheet devices. Further, the backside-connecting via provides a current path between a buried power rail (BPR) and a first transistor of the plurality of resistors. Accordingly, such embodiments can provide a backside-connecting via with reduced resistance resulting from increased via volume, and increased via contact area with the buried power rail. Additionally, such embodiments can increase the scalability of the BSPDN due to a larger process window for backside-connecting via metal fill. Additionally, such embodiments can improve the performance of the see above comment BSPDN due to reduced resistance between the backside-connecting via and the transistors.

Embodiments are disclosed for a method for fabricating a semiconductor device. The method includes depositing a dielectric layer over a plurality of nanosheet devices. The method further includes performing an etch-back of the dielectric layer to form multiple nanosheet spacers that surround each of the plurality of nanosheet devices. Additionally, the method includes forming a backside-connecting via between two of the nanosheet devices. Further, the backside-connecting via provides a current path between a buried power rail (BPR) and a first nanosheet device of the plurality of nanosheet devices. Additionally, the backside-connecting via is formed without metal voids. Advantageously, such embodiments provide a method that fabricates semiconductor devices without voids in the backside-connecting via. Accordingly, such embodiments represent an improvement over the fabrication of current semiconductor devices due to a void-free metal fill, increased via volume, and increased contact area between the backside-connecting via and the BPR.

Embodiments are disclosed for a method for fabricating a semiconductor device. The method includes depositing a dielectric layer over a plurality of nanosheet devices. The method further includes performing an etch-back of the dielectric layer to form multiple nanosheet spacers that surround each of the plurality of nanosheet devices. Additionally, the method includes forming a backside-connecting via between two of the nanosheet devices. Further, the backside-connecting via provides a current path between a buried power rail (BPR) and a first nanosheet device of the plurality of nanosheet devices. Additionally, the backside-connecting via is formed without metal voids. Further, the method includes forming a device layer having the first transistor, a second transistor, a first spacer, and a second spacer. Additionally, the first transistor is in contact with the first spacer. Further, the second transistor is in contact with the second spacer. Additionally, the first transistor neighbors the second transistor. Further, the method includes forming the backside-connecting via in contact with the first transistor and a backside power distribution network (BSPDN). Advantageously, such embodiments provide a method that fabricates semiconductor devices without voids in the backside-connecting via. Accordingly, such embodiments represent an improvement over the fabrication of current semiconductor devices due to a void-free metal fill, increased via volume, and increased contact area between the backside-connecting via and the BPR.

The present summary is not intended to illustrate each aspect of every implementation of, and/or every embodiment of the present disclosure.

### BRIEF DESCRIPTION OF THE DRAWINGS

The drawings included in the present application are incorporated into, and form part of, the specification. They illustrate embodiments of the present disclosure and, along with the description, serve to explain the principles of the disclosure. The drawings are only illustrative of certain embodiments and do not limit the disclosure.

FIG. 1 is a cross-sectional view of an example semiconductor device array, in accordance with some embodiments of the present disclosure.

FIG. 2 is a process flow chart of an example method for fabricating an example semiconductor device array, in accordance with some embodiments of the present disclosure.

FIGS. 3A, 3B, 3C, 3D, 3E, 3F, 3G, 3H, 3I, 3J, 3K, 3L, 3M, and 3N, are example fabrication states of an example semiconductor device array being constructed, in accordance with some embodiments of the present disclosure.

While the present disclosure is amenable to various modifications and alternative forms, specifics thereof have been shown by way of example in the drawings and will be described in detail. It should be understood, however, that the intention is not to limit the present disclosure to the embodiments described. On the contrary, the intention is to cover all modifications, equivalents, and alternatives falling within the spirit and scope of the present disclosure.

### DETAILED DESCRIPTION

As stated previously, backside-connecting vias are fabricated in a trench between two transistors. However, because the aspect ratio of the trench is relatively high, filling the trench with metal can create voids, which increases the resistance of the formed backside-connecting via. Widening the trench may reduce the aspect ratio, and thus, improve the metal fill by eliminating voids, increase the via volume, and increase the contact area with the buried power rail. However, such widening may bring the backside-connecting via into electrical contact with a neighboring transistor, which creates a fatal short.

Accordingly, some embodiments of the present disclosure can fabricate a semiconductor device array having a backside-connecting via with a reduced aspect ratio in comparison to current semiconductor devices. Additionally, such embodiments may isolate the backside-connecting via from the active components (e.g., transistors) of the device layer with dielectric spacers positioned between the backside-connecting via and neighboring transistors. In this way, such embodiments can provide a backside-connecting via with reduced resistance resulting from eliminated voids, increased via volume, and increased via contact area with the buried power rail. Further, such embodiments can increase the scalability of the BSPDN due to a larger process window for backside-connecting via metal fill. The larger process window means it is possible to manufacture the opening for the backside-connecting via more robustly than current solutions, because nanosheet spacers protect the sidewalls of the nanosheet devices. This protection enables a process of longer trench formation by etching, which makes it possible to create wider trenches than possible in current techniques. Additionally, some embodiments of the present disclosure can improve the performance of the BSPDN due to reduced resistance between the backside-connecting via and the transistors.

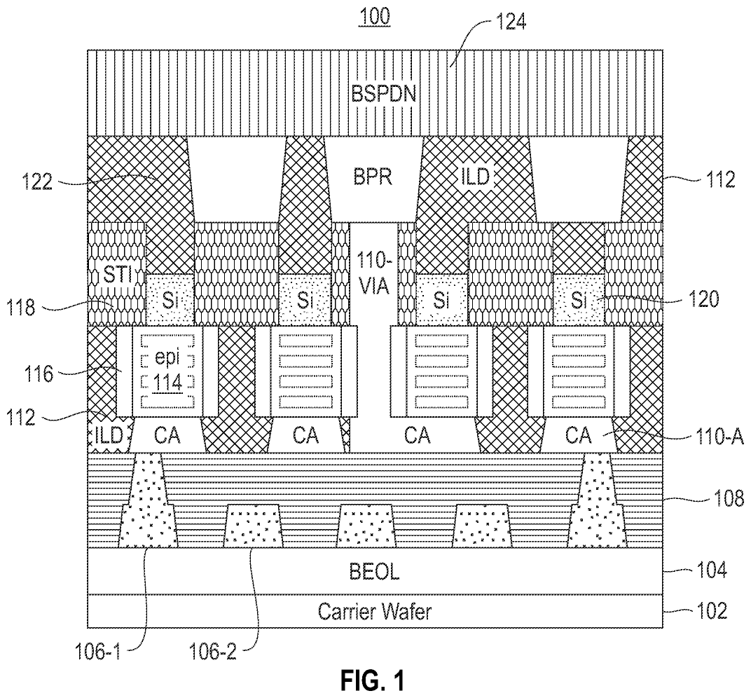

FIG. 1 is a cross-sectional view of an example semiconductor device array 100, in accordance with some embodiments of the present disclosure. The example semiconductor device array 100 includes, from bottom to top, a carrier wafer 102, back end of line (BEOL) interconnect layers 104, power rails 106-1, tracks 106-2, dielectric layer 108, contacts (CA) 110-A, backside-connecting via 110-VIA, interlayer dielectric (ILD) 112, nanosheet devices 114 (shown here behind the source drain epitaxy (epi) of the nanosheet device), nanosheet spacers 116, shallow trench isolation (STI) layer 118, silicon layer 120, buried power rails 122, and backside power distribution network (BSPDN) layer 124.

The carrier wafer 102 can be a layer of silicon (Si), for example, bonded to the BEOL interconnect layers 104. The BEOL interconnect layers 104 include the first layer of metal on the carrier wafer 102, contacts, insulating layers of dielectrics, and the like. The metal layers may form logical circuits. The power rails 106-1 may provide the source/drain voltage to/from the nanosheet devices 114. Additionally, the tracks 106-2 provide electrically conductive paths for configuring the example semiconductor device array 100. Further, the dielectric layer 108 can provide isolation between the power rails 106-1 and tracks 106-2; and, between the tracks 106-2, contacts 110-A, and backside-connecting via 110-VIA. The contacts 110-A are device layer conductive metal contacts that are in electrical contact with the source/drain (S/D) epitaxy of the nanosheet devices 114, thus connecting the nanosheet devices 114 to the power rails 106-1.

As shown, the backside-connecting via 110-VIA is located between neighboring nanosheet spacers of neighboring nanosheet devices. Further, the backside-connecting via 110-VIA provides an interconnect between the BPR 122 and the second nanosheet device 114 from the right (as shown). According to some embodiments of the present disclosure, the backside-connecting via 110-VIA is without metal voids in a conductive metal such as, cobalt (Co), tungsten (W), and the like. As shown, the bottom of the backside-connecting via 110-VIA has a bottom in contact with the BPR 122. According to some embodiments of the present disclosure, the width of the bottom is at least one half of the width of the top of the backside-connecting via 110-VIA. Further, according to some embodiments of the present disclosure, the width of the backside-connecting via 110-VIA beneath the first spacer and the second spacer is wider than the width of the backside-connecting via between the neighboring nanosheet spacers of the neighboring nanosheet devices.

The ILD 112 may be a dielectric material with a relatively low-k constant (e.g., k=3.9 or less). The nanosheet devices 114 can be field effect transistors (FETs), such as nanosheet FETs, vertical FETs (VTFETs), or FinFETs.

The nanosheet spacers 116 are a dielectric material that isolates the nanosheet devices 114 from the backside-connecting via 110-VIA. More specifically, the nanosheet spacers 116 can be an isolating dielectric metal such as, silicon nitride (SiNₓ), silicon boron carbonitride (SiBCN), silicon boronitride (SiBN), silicon carbon nitride (SiCN), silicon oxynitride (SiON), and the like. Additionally, the spacers that surround the backside-connecting via 110-VIA prevent the backside-connecting via 110-VIA from coming into electrical contact with the neighboring nanosheet devices 114, thus creating a short. As shown, the backside-connecting via 110-VIA can be in contact with nanosheet spacers 116 that isolate the backside-connecting via 110-VIA and the neighboring nanosheet devices 114. In some embodiments, the nanosheet spacers can have a thickness between five and twenty nanometers.

Advantageously, the nanosheet spacers 116 enable the formation of a backside-connecting via (BCV) trench with a reduced aspect ratio in comparison to current semiconductor devices. As such, some embodiments of the present disclosure can eliminate the incidence of voids in the formation of the backside-connecting via 110-VIA in the BCV trench. Additionally, such embodiments can increase the volume of the backside-connecting via 110-VIA, and increase the contact area between the via and the buried power rail 122. In this way, such embodiments can reduce the resistance of the example semiconductor device array 100, in comparison to current semiconductor devices.

Additionally, the STI layer 118 can be a trench filled with a dielectric material that isolates between different device regions, and isolates the device layer from the BPR 122. Further, the BPRs 122 are metal rails that provide the source/drain current to/from the nanosheet devices 114. Additionally, the BSPDN 124 delivers electric current from a power source to the BPR's 122. More specifically, the BSPDN 124 may include the solder pads, metal tracks, insulators, resistors, capacitors, interconnect structure like metal lines and vias, and the like, providing a conductive path between the power source and the BPRs 122.

While the example semiconductor device array 100 includes nanosheet transistor devices, these devices are merely an example of transistors that may be included. However, in some embodiments of the present disclosure, the semiconductor device may include other transistors, such as planar FETs, vertical transistors (VTFETs) or FinFETs, semiconductor memory structures, and the like.

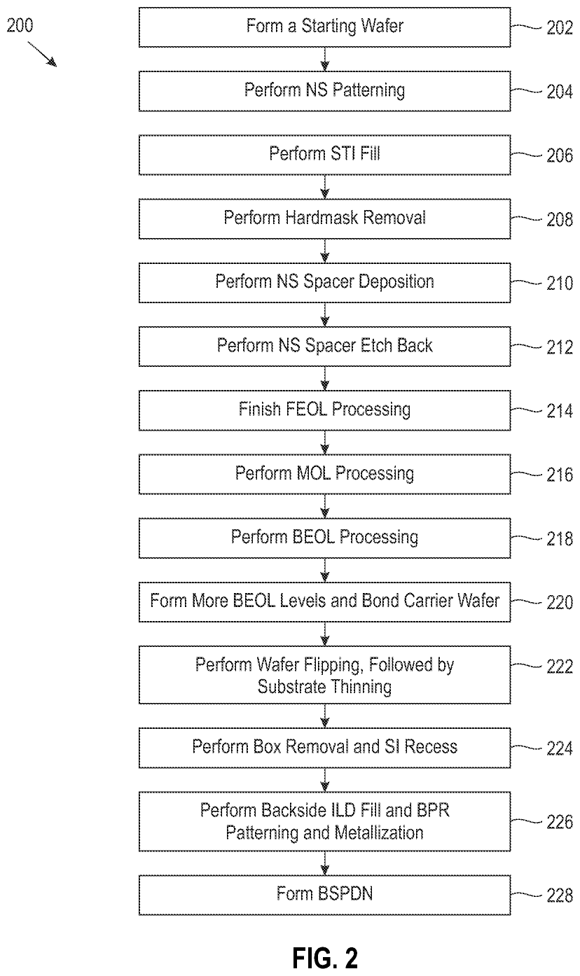

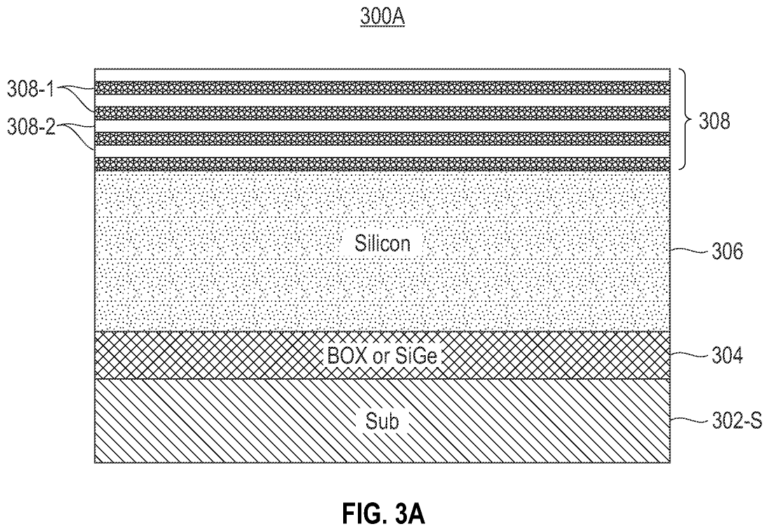

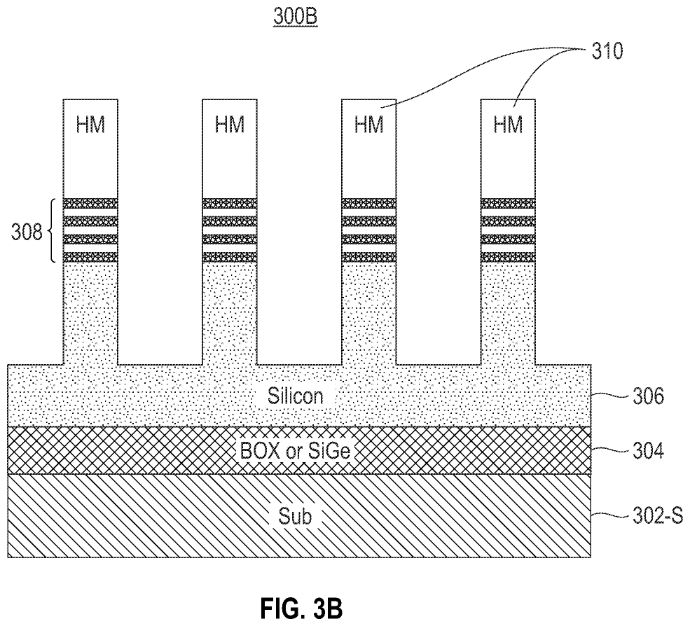

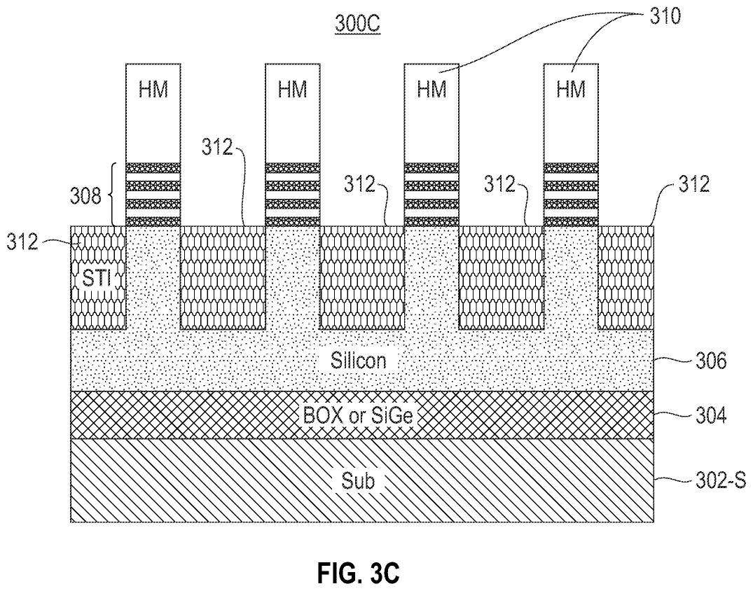

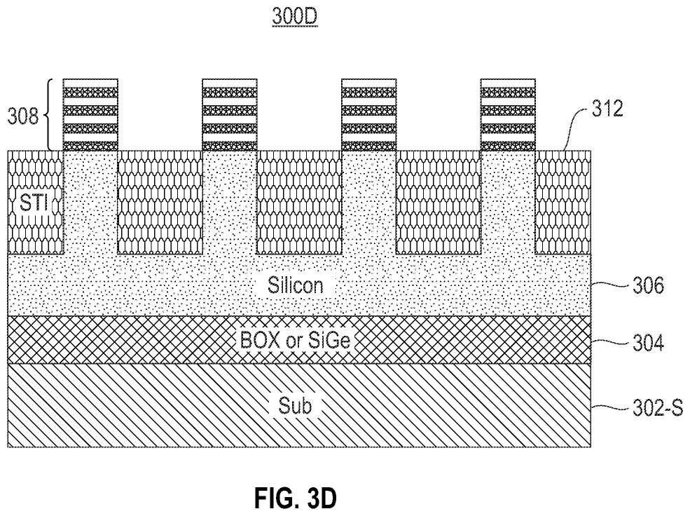

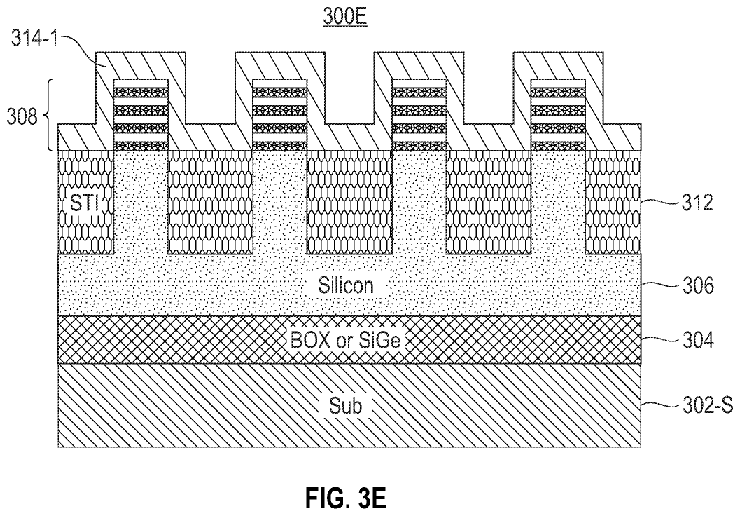

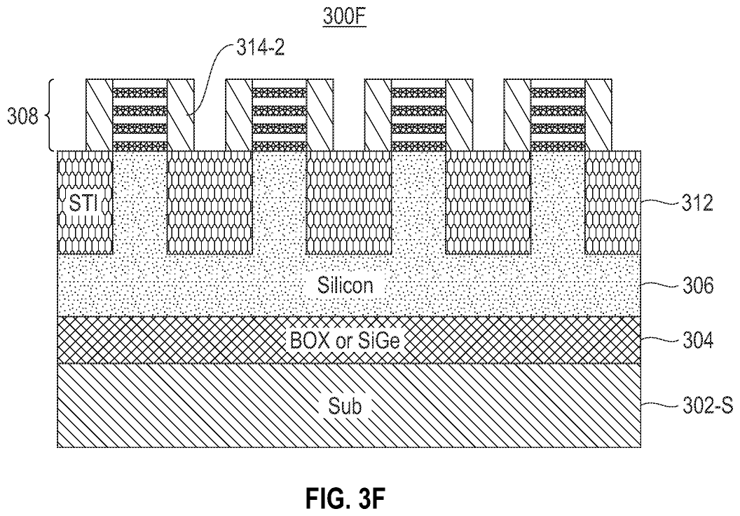

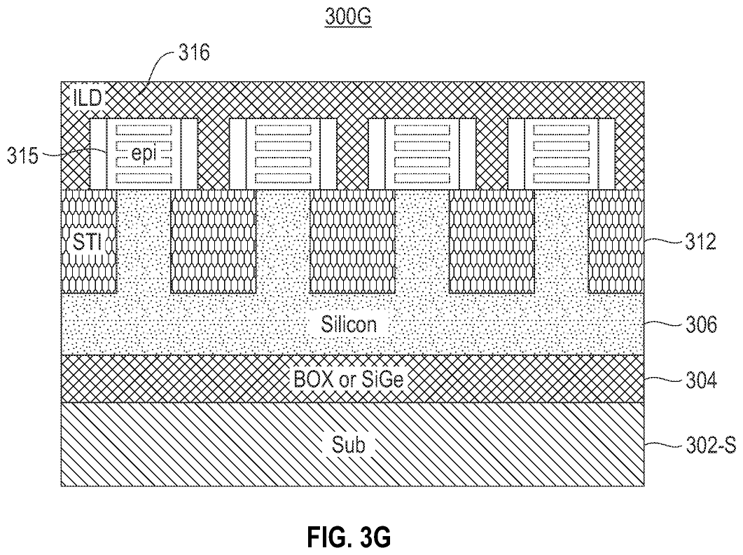

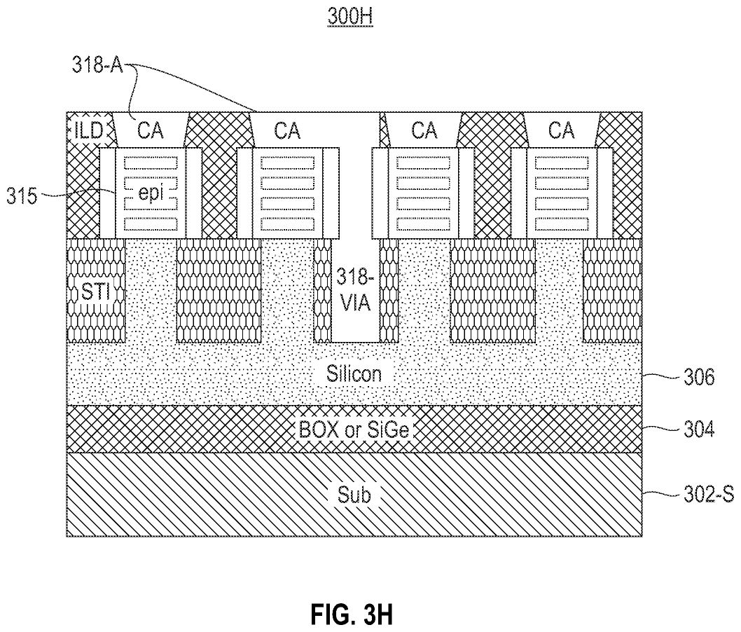

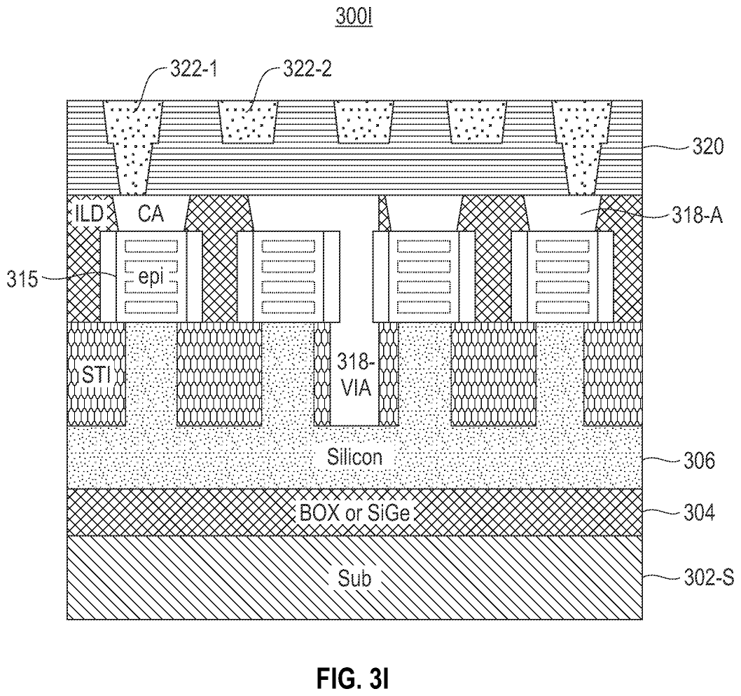

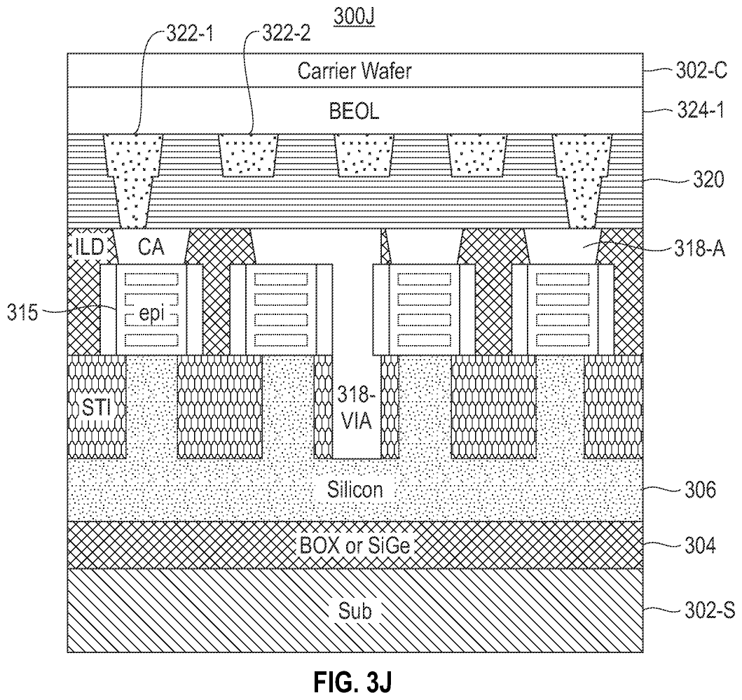

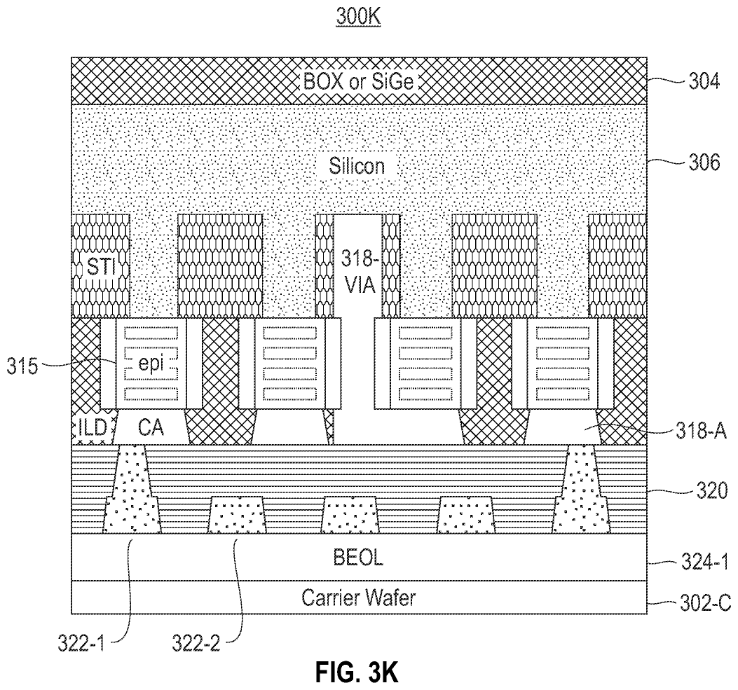

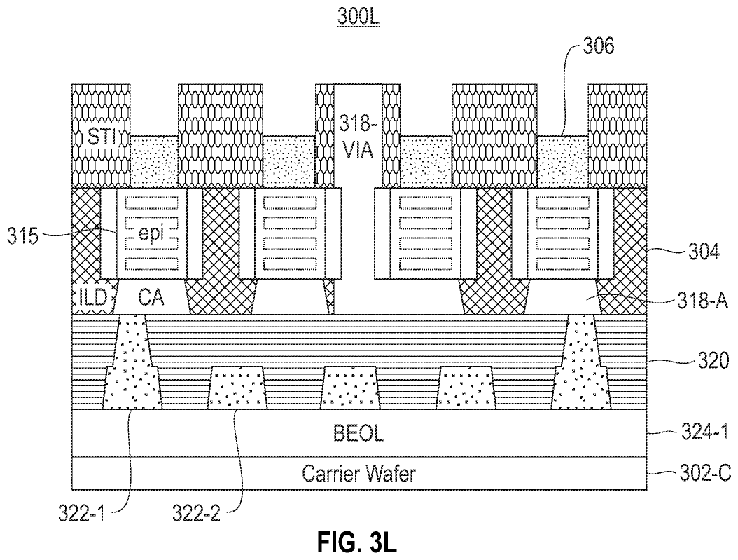

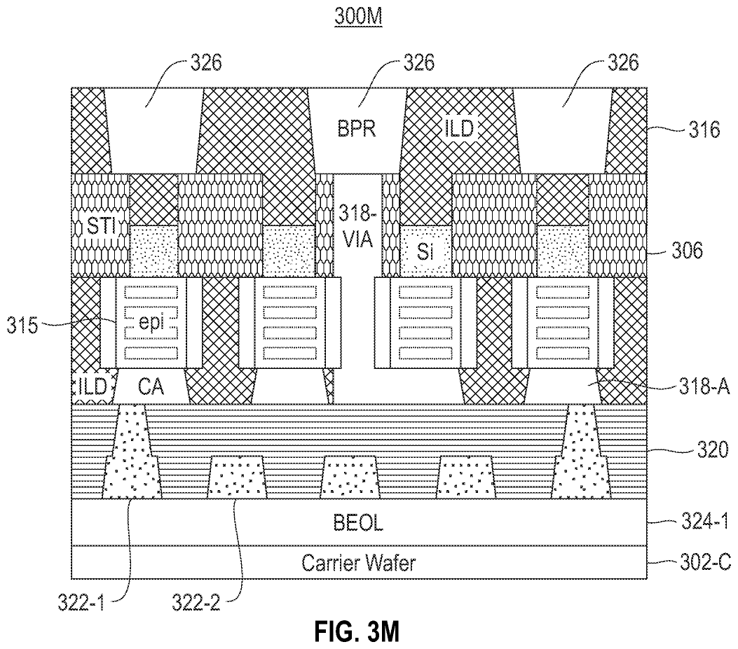

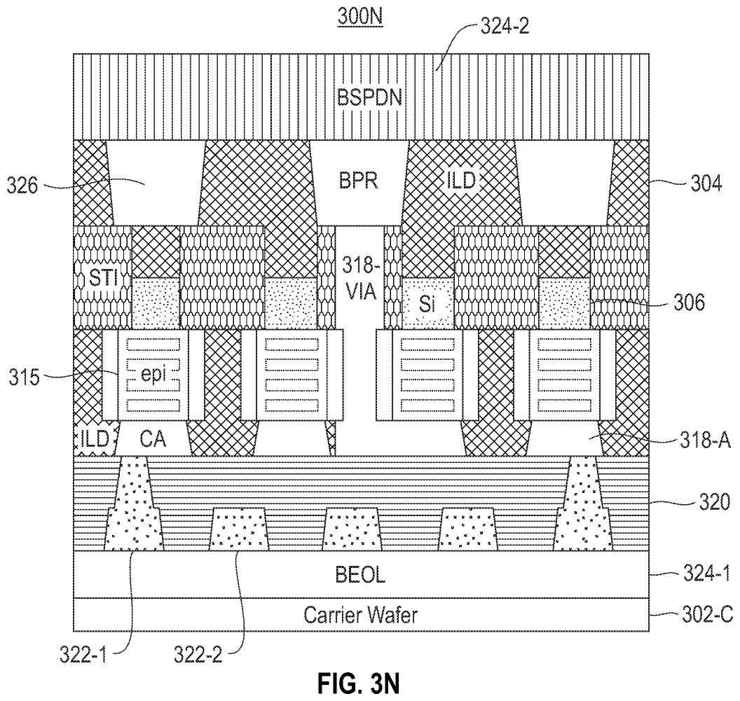

FIG. 2 is a process flow chart of an example method 200 for fabricating a semiconductor device array, in accordance with some embodiments of the present disclosure. In some embodiments, one or more fabrication tools can perform the method 200. This method can fabricate a semiconductor device array, such as the example semiconductor device array 100, described with respect to FIG. 1. For clarity, the method 200 is described with respect to FIGS. 3A through 3N.

FIGS. 3A, 3B, 3C, 3D, 3E, 3F, 3G, 3H, 3I, 3J, 3K, 3L, 3M, and 3N are example fabrication states of an example semiconductor device array being constructed, in accordance with some embodiments of the present disclosure. The example semiconductor device array can include, for example, the example semiconductor device array 100, described with respect to FIG. 1. Similar to FIG. 1, the FIGS. 3A through 3N represent cross-sectional views of the example semiconductor device array (being constructed) after each operation of the method 200, as described in greater detail below.

Referring back to FIG. 2, at operation 202, the fabrication tool can form a starting wafer. A starting wafer may be formed so as to include a layer of substrate material, a layer of sacrificial etch stop material, a layer of silicon, and a nanosheet stack made up of multiple alternating sacrificial layers and semiconductor layers. Such a wafer may be prepared such that the layer of sacrificial etch stop material is formed in direct contact with and covering an uppermost surface of the layer of substrate material, and such that the layer of silicon is formed in direct contact with (and covering) an uppermost surface of the layer of sacrificial etch stop material. Further, the nanosheet stack is formed in direct contact with and covering an uppermost surface of the layer of silicon. In accordance with some embodiments of the present disclosure, the layer of substrate material may be a silicon-containing material. Illustrative examples of silicon-containing materials suitable for the layer of substrate material include, but are not limited to, silicon, silicon germanium, epitaxial silicon, amorphous silicon, and multi-layers thereof. Although silicon (Si) is the semiconductor material typically used in wafer fabrication, alternative semiconductor materials can be employed, such as, but not limited to, gallium arsenide, indium gallium arsenide, indium phosphide, cadmium telluride, zinc selenide, and other III-V compound semiconductors and/or II-VI compound semiconductors. The III-V compound semiconductors are materials that include at least one element from Group III of the Periodic Table of Elements and at least one element from Group V of the Periodic Table of Elements. II-VI compound semiconductors are materials that include at least one element from Group II of the Periodic Table of Elements and at least one element from Group VI of the Periodic Table of Elements.

In accordance with some embodiments of the present disclosure, the layer of sacrificial etch stop material may be formed of an insulative material. For example, the sacrificial etch stop material may be a dielectric layer, such as an oxide, and may be referred to as a buried oxide (BOX) layer. The dielectric layer may be any suitable dielectric, oxide, or the like, and it may electrically isolate further structures from the layer of substrate material.

In accordance with some embodiments of the present disclosure, the nanosheet stack may be formed such that a first sacrificial layer is formed in direct contact with and covering the layer of silicon. A first semiconductor layer is then formed in direct contact with and covering the first sacrificial layer. A number of additional sacrificial layers and semiconductor layers are alternatingly formed on top of one another in this manner. In accordance with some embodiments of the present disclosure, four semiconductor layers are formed. However, in alternative embodiments, more or fewer than four semiconductor layers may be formed. In accordance with some embodiments of the present disclosure, the uppermost layer of the nanosheet stack is a semiconductor layer. However, in alternative embodiments, a sacrificial layer may form the uppermost layer of the nanosheet stack. In such embodiments, a sacrificial layer may form the lowermost layer and the uppermost layer of the nanosheet stack such that the nanosheet stack includes a greater number of sacrificial layers than semiconductor layers.

In accordance with some embodiments of the present disclosure, the sacrificial layers may be composed of, for example, silicon-germanium (e.g., SiGe, wherein the amount of Germanium is between approximately 15% and approximately 30%). Further, the semiconductor layers may be composed of, for example, silicon. For clarity, operation 202 is further described with respect to FIG. 3A.

FIG. 3A is an example fabrication state 300A of an example semiconductor device array being constructed, according to some embodiments of the present disclosure. More specifically, the example fabrication state 300A includes a substrate layer 302-S, sacrificial etch stop layer 304, a silicon layer 306, and nanosheet stack 308. The nanosheet stack 308 includes alternating sacrificial layers 308-1 and semiconductor layers 308-2. In this way, the example fabrication state 300A can represent a state of the example semiconductor device array being constructed after performing operation 202.

Referring back to FIG. 2, at operation 204, the fabrication tool can perform nanosheet (NS) patterning. Performing nanosheet patterning can involve patterning and removing portions of the nanosheet stack 308 and the underlying silicon layer 306 to form trenches that will subsequently be filled with shallow trench isolation material. More specifically, in such embodiments, a hardmask is selectively applied on top of the nanosheet stack in areas where the nanosheet stack is not removed. The materials of those areas that are not covered by the hardmask are then removed, such as by etching. More specifically, the layers of the nanosheet stack 308 and a portion of the silicon layer 306 that are not covered by the hardmask are removed. The removal of these portions of the prepared wafer can be achieved by etching or by another suitable technique. For clarity, operation 204 is described with respect to FIG. 3B.

FIG. 3B is an example fabrication state 300B of the example semiconductor device array being constructed, according to some embodiments of the present disclosure. As shown, a hardmask (HM) 310 has been applied to cover portions of the nanosheet stack 308. Further, materials in the areas that are not covered by the hardmask 310 are removed. In particular, the nanosheet stack 308 and a portion of the silicon layer 306 that are not covered by the hardmask 310 are removed to form trenches. In other words, relatively long and narrow fins of the silicon layer 306 and the nanosheet stack 308 are formed underneath each area of hardmask 310. Notably, the removal of material only extends into the silicon layer 306 of the wafer. In other words, the sacrificial etch stop layer 304 and substrate layer 302-S are unaffected by the removal of material in the performance of operation 204. In this way, the example fabrication state 300B can represent a state of the example semiconductor device array being constructed after performing operation 204.

Referring back to FIG. 2, at operation 206, the fabrication tool can perform STI fill. Performing STI fill can involve filling the trenches formed at operation 204 with an STI material. The STI material can be, for example, a silicon dioxide material. Filling the trenches may include, for example, depositing the STI material onto the wafer. The trenches are filled such that the STI material covers all surfaces of the silicon layer 306 exposed by the formation of the trenches. More specifically, the trenches are filled such that an uppermost surface of the STI material is substantially coplanar with the uppermost surface of the silicon layer 306. In other words, the uppermost surface of the STI material does not cover any surfaces of the lowermost sacrificial layer 308-1 of the nanosheet stack 308. In accordance with some embodiments of the present disclosure, planarization may be used to ensure that the uppermost surface of the STI material is substantially coplanar with the uppermost surface of the silicon layer 306 and does not cover any surfaces of the lowermost sacrificial layer 308-1 of the nanosheet stack 308. For clarity, operation 206 is described with respect to FIG. 3C.

FIG. 3C is an example fabrication state 300C of the example semiconductor device array being constructed, according to some embodiments of the present disclosure. As shown, an STI material 312 fills the trenches up to the bottom of the lowermost sacrificial layer 308-1. As shown, an uppermost surface of the STI material 312 is substantially coplanar with an uppermost surface of the silicon layer 306. More specifically, the uppermost surface of the STI material 312 is substantially coplanar with the uppermost surface of the silicon layer 306 where covered by the hardmask 310 (as shown in FIG. 3B) and not etched. Accordingly, the uppermost surface of the STI material 312 does not cover any surfaces of the lowermost sacrificial layer 308-1 of the nanosheet stack 308. In this way, example fabrication state 300C can represent a state of the example semiconductor device array being constructed after performing operation 206.

Referring back to FIG. 2, at operation 208, the fabrication tool can perform hardmask removal. Performing hardmask removal can involve removing the hardmask 310 from the nanosheet stacks 308. For clarity, operation 208 is described with respect to FIG. 3D.

FIG. 3D is an example fabrication state 300D of the example semiconductor device array being constructed, according to some embodiments of the present disclosure. In comparison to example fabrication state 300C, example fabrication state 300D shows the nanosheet stacks 308 remaining after removing the hardmask 310. In this way, example fabrication state 300D can represent a state of the example semiconductor device array being constructed after performing operation 208.

Referring back to FIG. 2, at operation 210, the fabrication tool can perform nanosheet (NS) spacer deposition. Performing nanosheet spacer deposition can involve depositing dielectric material covering the STI material 312, and the nanosheet stacks 308. For clarity, operation 210 is further described with respect to FIG. 3E.

FIG. 3E is an example fabrication state 300E of an example semiconductor device array being constructed, in accordance with some embodiments of the present disclosure. In comparison to example fabrication state 300D, the example fabrication state 300E additionally includes dielectric layer 314-1. As shown, the nanosheet deposition can leave trenches between the nanosheet stacks 308. In this way, FIG. 3E can represent a state of the example semiconductor device array being constructed after operation 210.

Referring back to FIG. 2, at operation 212, the fabrication tool can perform nanosheet spacer etch back. Performing nanosheet spacer etch back can involve forming nanosheet spacers by etch-back of the dielectric layer 314-1 using directional reactive ion etch (RIE). The directional RIE removes spacer material from the horizontal surfaces, not the vertical surfaces, thus leaving the spacers remaining at the sidewalls of the nanosheet stacks. For clarity, operation 212 is further described with respect to FIG. 3F.

FIG. 3F is an example fabrication state 300F of the example semiconductor device array being constructed, in accordance with some embodiments of the present disclosure. In comparison to example fabrication state 300E, the example fabrication state 300F includes the nanosheet spacers 314-2, which remain after etch-back of the dielectric layer 314-1. As shown, the etch-back deepens the trenches created by the nanosheet deposition, and thus exposes a portion of the STI material 312. In this way, FIG. 3F can represent a state of the example semiconductor device array being constructed after operation 212.

Referring back to FIG. 2, at operation 214, the fabrication tool can finish front end of line (FEOL) processing. The FEOL, also referred to herein as the device layer, is a layer of single transistors and static random access memory (SRAM) area. The SRAM area is an area where nFETs and pFETs are densely integrated to form memory devices. Integrated circuits are the FEOL connected by the BEOL and/or BSPDN. Finishing FEOL processing can involve forming the FEOL structure. The formation of such FEOL structures is not within the scope of this disclosure and may be performed using known methods and techniques. For clarity, operation 214 is further described with respect to FIG. 3G.

FIG. 3G is an example fabrication state 300G of the example semiconductor device array being constructed, in accordance with some embodiments of the present disclosure. In example fabrication state 300G, the sacrificial and channel layers are recessed in the source/drain (S/D) region. Additionally, the nanosheet stacks 308 outside the gates have been surrounded by an epitaxy material, e.g., source/drain (S/D) epitaxial 315 to form transistors, i.e., nanosheet devices. Additionally, the areas between the nanosheet spacers 314-2 surrounding the S/D epitaxy have been filled with an ILD material 316. Accordingly, the ILD material 316 is in direct contact with the uppermost horizontal surfaces of the STI material 312. In other words, a lowermost surface of the ILD material 316 is in direct contact with the uppermost surface of the STI material 312. Because the S/D epitaxy 315 are the outermost structural elements of the nanosheet devices, the reference numeral 315 may also be used herein to indicate the nanosheet devices.

Further, the lowermost surface of the ILD material 316 may be in contact with the lowermost surfaces of the S/D epitaxy 315 of the nanosheet devices. Additionally, an uppermost surface of the ILD material 316 is arranged above the uppermost surfaces of the epitaxy material of the transistors and is planarized. In this way, FIG. 3G can represent the example semiconductor device array being constructed after operation 214.

Referring back to FIG. 2, at operation 216, the fabrication tool can perform middle of line (MOL) processing. Performing MOL processing can involve patterning MOL contacts on the example semiconductor device array. Additionally, MOL processing can involve removing material to form the backside-connecting via (BCV) trench. Further, MOL processing involves metallization. In particular, the patterned contact areas are filled with a metal material to form contact pads, also referred to herein as MOL contacts, and the BCV trench is filled with the metal material to form the backside-connecting via. For clarity, operation 216 is further described with respect to FIG. 3H.

FIG. 3H is an example fabrication state 300H of the example semiconductor device array being constructed, in accordance with some embodiments of the present disclosure. In comparison to example fabrication state 300G, the example fabrication state 300H additionally includes contacts (CA) 318-A and the backside-connecting via 318-VIA. In this way, FIG. 3H can represent the example semiconductor device array being constructed after operation 216.

Referring back to FIG. 2, at operation 218, the fabrication tool can perform the BEOL processing. Performing BEOL processing can involve forming the BEOL structures in a dielectric material. In accordance with some embodiments of the present disclosure, the performance of operation 218 can include the performance of standard BEOL processes to form BEOL structures. The processes and formation of such BEOL structures is not within the scope of this disclosure and may be performed using known methods and techniques. For clarity, operation 218 is further described with respect to FIG. 3I.

FIG. 3I is an example fabrication state 300I of the example semiconductor device array being constructed, in accordance with some embodiments of the present disclosure. As shown, a first layer of BEOL is formed, which includes interconnect structures 322 (i.e., power rails 322-1 and metal tracks 322-2) in a surrounding dielectric material 320. The first layer of BEOL is formed above the uppermost surface of the ILD material 316 and connecting to the MOL contacts 318-A. In this way, FIG. 3I can represent the example semiconductor device array being constructed after operation 218.

Referring back to FIG. 2, at operation 220, the fabrication tool can form more BEOL levels. Subsequently the finished FEOL/BEOL containing wafer is bonded to a carrier wafer. Forming more BEOL levels and bonding the carrier wafer involves forming a number of additional layers of BEOL interconnect structures to establish the predetermined functionality of the example semiconductor device array. Additionally, in such embodiments, following the formation of the layers of BEOL interconnect structures, a carrier wafer is bonded to the uppermost layer of BEOL interconnect structures to enable flipping the example semiconductor device array for further processing. For clarity, operation 220 is further described with respect to FIG. 3J.

FIG. 3J is an example fabrication state 300J of the example semiconductor device array being constructed, in accordance with some embodiments of the present disclosure. In comparison to example fabrication state 300I, the example fabrication state 300J additionally includes the BEOL layers 324-1 and carrier wafer 302-C. The BEOL layers 324-1 can include any number (including zero) of additional layers of BEOL interconnect structures that may be similar to those illustrated by the first layer of BEOL interconnect structures 322 formed in the surrounding dielectric material 320. Additionally, the example fabrication state 300J shows the carrier wafer 302-C bonded to the uppermost layer of BEOL interconnect structures (i.e., BEOL layers 324-1). In this way, FIG. 3J can represent the example semiconductor device array being constructed after operation 220.

Referring back to FIG. 2, at operation 222, the fabrication tool can perform wafer flipping, followed by substrate thinning. Performing the wafer flip can involve reversing the vertical orientation of the example semiconductor device array being constructed. Additionally, the substrate thinning can involve removing the substrate 302-S, by grinding and etching, thus exposing the sacrificial etch stop layer 304. For clarity, operation 222 is further described with respect to FIG. 3K.

FIG. 3K is an example fabrication state 300K of the example semiconductor device array being constructed, in accordance with some embodiments of the present disclosure. In comparison to example fabrication state 300J, the carrier wafer 302-C is arranged at the bottom of FIG. 3K and the substrate layer 302-S has been removed such that the sacrificial etch stop layer 304 is arranged at the top of FIG. 3K. In this way, FIG. 3K can represent the example semiconductor device array being constructed after operation 222.

Referring back to FIG. 2, at operation 224, the fabrication tool can perform BOX removal and silicon recess. Performing BOX removal can involve removing the sacrificial etch stop layer 304 by a selective wet etching process. Additionally, the silicon recess can involve removing a portion of the silicon layer 306 such that an uppermost surface of the backside-connecting via 318-VIA is exposed. The removal of the portion of the silicon layer 306 further exposes portions of the STI material 312 previously encapsulated by the silicon layer 306. For clarity, operation 224 is further described with respect to FIG. 3L.

FIG. 3L is an example fabrication state 300L of the example semiconductor device array being constructed, in accordance with some embodiments of the present disclosure. In comparison to example fabrication state 300K, the example fabrication state 300L no longer includes the sacrificial etch stop layer 304. Additionally, the silicon layer 306 is partially removed such that an uppermost surface of the backside-connecting via 318-VIA is exposed. Additionally, the removal of the portion of the silicon layer 306 further exposes portions of the STI material 312 previously encapsulated by the silicon layer 306. As shown, the silicon layer 306 has been recessed relative to the structures encapsulated therein. In this way, FIG. 3L can represent the example semiconductor device array being constructed after operation 224.

Referring back to FIG. 2, at operation 226, the fabrication tool can perform backside ILD fill and BPR patterning and metallization. Operation 226 involves forming backside interconnect structures, including a buried power rail, on the example semiconductor device array. In particular, the formation of the backside interconnect structures includes performing a backside ILD fill to fill the open areas left by recessing the silicon layer 306, and to further form a layer of ILD material on top of the STI material 312 and the backside-connecting via 318-VIA. In such embodiments, the formation of backside interconnect structures can further include patterning for the backside structures, for example, by selectively masking and removing portions of the ILD material 320. In such embodiments, the formation of backside interconnect structures can further include metallization to fill the voids in the ILD material 320 that were formed during patterning with metal material. In such embodiments, the buried power rail is formed during this metallization. In other words, part of the metal material that fills the voids in the ILD material forms the buried power rail. For clarity, operation 226 is further described with respect to FIG. 3M.

FIG. 3M is an example fabrication state 300M of the example semiconductor device array being constructed, in accordance with some embodiments of the present disclosure. As shown, an ILD material 316 has been formed to cover exposed surfaces of the silicon layer 306, the STI material 312, and the backside-connecting via 318-VIA. Additionally, the ILD material 316 has been patterned and metallized such that metal regions 326 are formed with a metal material. The middle metal region (as shown) is a buried power rail and is in direct contact with the backside-connecting via 318-VIA. Accordingly, the backside-connecting via 318-VIA is a via establishing electrical connection between the buried power rail and the nanosheet transistor. The buried power rail may be in direct contact with the STI material 312 on either side of the backside-connecting via 318-VIA. In this way, FIG. 3M can represent the example semiconductor device array being constructed after operation 226.

Referring back to FIG. 2, at operation 228, the fabrication tool can form the backside power distribution network (BSPDN). Forming the BSPDN can involve forming involve fabricating the elements of the BSPDN such as, metallic lines, and ILD material. For clarity, operation 228 is further described with respect to FIG. 3N.

FIG. 3N is an example fabrication state 300N of the example semiconductor device array being constructed, in accordance with some embodiments of the present disclosure. As shown, BSPDN structures 324-2 have been formed on the example semiconductor device array such that the BSPDN structures 324-2 are in direct contact with the ILD material 316 and with the metal regions 326. For simplicity, the BSPDN structures 324-2 are illustratively represented as a single feature. However, the BSPDN structures 324-2 may include one or more layers of BSPDN structures, similar to the BEOL on the opposite side of the device layer, built on top of one another depending on the functionalities of the example semiconductor device array. In this way, the example fabrication state 300N represents an example semiconductor device array such as, the example semiconductor device array 100, described with respect to FIG. 1.

For purposes of this description, certain aspects, advantages, and novel features of the embodiments of this disclosure are described herein. The disclosed processes, and systems should not be construed as being limiting in any way. Instead, the present disclosure is directed toward all novel and nonobvious features and aspects of the various disclosed embodiments, alone and in various combinations and sub-combinations with one another. The processes, and systems are not limited to any specific aspect or feature or combination thereof, nor do the disclosed embodiments require that any one or more specific advantages be present, or problems be solved.

Although the operations of some of the disclosed embodiments are described in a particular, sequential order for convenient presentation, it should be understood that this manner of description encompasses rearrangement, unless a particular ordering is required by specific language set forth below. For example, operations described sequentially can in some cases be rearranged or performed concurrently. Moreover, for the sake of simplicity, the attached figures may not show the various ways in which the disclosed processes can be used in conjunction with other processes. Additionally, the description sometimes uses terms like “provide” or “achieve” to describe the disclosed processes. These terms are high-level abstractions of the actual operations that are performed. The actual operations that correspond to these terms can vary depending on the particular implementation and are readily discernible by one of ordinary skill in the art.

As used in this application and in the claims, the singular forms “a,” “an,” and “the” include the plural forms unless the context clearly dictates otherwise. Additionally, the term “includes” means “comprises.”

The descriptions of the various embodiments of the present disclosure have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to explain the principles of the embodiments, the practical application or technical improvement over technologies found in the marketplace, or to enable others of ordinary skill in the art to understand the embodiments disclosed herein.

A non-limiting list of examples are provided hereinafter to demonstrate some aspects of the present disclosure.

Example 1 is a semiconductor device array. The device includes a backside power distribution network (BSPDN); a buried power rail (BPR) in contact with the BSPDN; a device layer comprising: a first transistor; a second transistor; a first spacer; and a second spacer, wherein: the first transistor is in contact with the first spacer; the second transistor is in contact with the second spacer; and the first transistor neighbors the second transistor; and a backside-connecting via that is in contact with the first transistor, the BPR, the first spacer, and the second spacer, wherein the backside-connecting via is in electrical contact with the first transistor.

Example 1 includes the device of example 1, including or excluding optional features. In this example, the second spacer prevents a short resulting from electrical contact between the second transistor and the backside-connecting via. Optionally, the backside-connecting via is without metal voids. Optionally, the backside-connecting via comprises a bottom in contact with the BPR, wherein a width of the bottom is at least one half of a top width of the backside-connecting via.

Example 2 includes the device of any one of examples 1 to 1, including or excluding optional features. In this example, a lower width of the backside-connecting via beneath the first spacer and the second spacer is wider than a middling width of the backside-connecting via between the first spacer and the second spacer.

Example 3 includes the device of any one of examples 1 to 2, including or excluding optional features. In this example, the first spacer and the second spacer comprise an isolating dielectric metal. Optionally, the isolating dielectric metal comprises a nitride based dielectric material. Optionally, the nitride based dielectric material is selected from a group consisting of silicon nitride (SiNₓ), silicon boron carbonitride (SiBCN), silicon boronitride (SiBN), silicon carbon nitride (SiCN), silicon oxynitride (SiON), and combinations thereof.

Example 5 includes the device of any one of examples 1 to 3, including or excluding optional features. In this example, each of the first transistor and the second transistor comprises a nanosheet device; and the first spacer and the second spacer each comprise a nanosheet spacer. Optionally, the metal is selected from a group consisting of Cobalt (Co) and Tungsten (W).

Example 6 includes the device of any one of examples 1 to 5, including or excluding optional features. In this example, the first spacer and a first additional spacer surround the first transistor; and the second spacer and a second additional spacer surround the second transistor.

Example 7 includes the device of any one of examples 1 to 6, including or excluding optional features. In this example, the first spacer and the second spacer have a thickness between five and twenty nanometers (nm).

Example 8 includes the device of any one of examples 1 to 7, including or excluding optional features. In this example, a third transistor is surrounded by a third spacer and a third additional spacer; and the third transistor is not in contact with the backside-connecting via.

Example 9 includes the device of any one of examples 1 to 8, including or excluding optional features. In this example, the first transistor and the second transistor are selected from a group consisting of a fin field effect transistor (FinFET), a vertical transport FET (VTFET), a semiconductor memory structure, and combinations thereof.

Example 10 is a semiconductor device array. The device includes a backside power distribution network (BSPDN); a buried power rail (BPR) in contact with the BSPDN; a device layer comprising: a first transistor; a second transistor; a first spacer; and a second spacer, wherein: the first transistor is in contact with the first spacer; the second transistor is in contact with the second spacer; the first spacer neighbors the second spacer; and the first transistor neighbors the second transistor; and a backside-connecting via that is in contact with the first transistor, the BPR, the first spacer, and the second spacer, wherein: the second spacer prevents a short resulting from electrical contact between the second transistor and the backside-connecting via; the backside-connecting via is in electrical contact with a top surface of the first transistor; the first spacer and a first additional spacer surround the first transistor; and the second spacer and a second additional spacer surround the second transistor.

Example 11 is a method for fabricating a semiconductor device, the method. The method includes depositing a dielectric layer over a plurality of transistors; performing a directional reactive ion etch-back of the dielectric layer to form a plurality of spacers that surround each of the plurality of transistors; and forming a backside-connecting via between two of the plurality of transistors, wherein the backside-connecting via provides a current path between a buried power rail (BPR) and a first transistor of the plurality of transistors.

Example 12 includes the method of example 11, including or excluding optional features. In this example, forming the backside-connecting via comprises forming the backside-connecting via without metal voids.

Example 13 includes the method of any one of examples 11 to 12, including or excluding optional features. In this example, the method includes forming a device layer comprising the first transistor, a second transistor, a first spacer, and a second spacer, wherein: the first transistor is in contact with the first spacer; the second transistor is in contact with the second spacer; and the first transistor neighbors the second transistor; forming the backside-connecting via in contact with the first transistor and a backside power distribution network (BSPDN). Optionally, the second spacer prevents a short between the backside-connecting via and the second transistor.

Example 14 includes the method of any one of examples 11 to 13, including or excluding optional features. In this example, method of claim 16, the plurality of transistors are selected from a group consisting of a fin field effect transistor (FinFET), a vertical transport FET (VTFET), a semiconductor memory structure, and combinations thereof.

What is claimed is:

1. A semiconductor device array comprising:
a backside power distribution network (BSPDN);
a buried power rail (BPR) in contact with the BSPDN;
a device layer comprising:
a first transistor;
a second transistor;
a first spacer; and
a second spacer, wherein:
the first transistor is in contact with the first spacer;
the second transistor is in contact with the second spacer; and
the first transistor neighbors the second transistor; and
a backside-connecting via that is in contact with the first transistor, the BPR, the first spacer, and the second spacer, wherein the backside-connecting via is in electrical contact with the first transistor.

2. The semiconductor device array of claim 1, wherein the second spacer prevents a short resulting from electrical contact between the second transistor and the backside-connecting via.

3. The semiconductor device array of claim 1, wherein the backside-connecting via is without metal voids.

4. The semiconductor device array of claim 3, wherein the backside-connecting via comprises a bottom in contact with the BPR, wherein a width of the bottom is at least one half of a top width of the backside-connecting via.

5. The semiconductor device array of claim 1, wherein a lower width of the backside-connecting via beneath the first spacer and the second spacer is wider than a middling width of the backside-connecting via between the first spacer and the second spacer.

6. The semiconductor device array of claim 1, wherein the first spacer and the second spacer comprise an isolating dielectric metal.

7. The semiconductor device array of claim 6, wherein the isolating dielectric metal comprises a nitride based dielectric material.

8. The semiconductor device array of claim 7, wherein the nitride based dielectric material is selected from a group consisting of silicon nitride (SiNₓ), silicon boron carbonitride (SiBCN), silicon boronitride (SiBN), silicon carbon nitride (SiCN), silicon oxynitride (SiON), and combinations thereof.

9. The semiconductor device array of claim 1, wherein:
each of the first transistor and the second transistor comprises a nanosheet device; and
the first spacer and the second spacer each comprise a nanosheet spacer.

10. The semiconductor device array of claim 9, wherein the metal is selected from a group consisting of Cobalt (Co) and Tungsten (W).

11. The semiconductor device array of claim 1, wherein:
the first spacer and a first additional spacer surround the first transistor; and
the second spacer and a second additional spacer surround the second transistor.

12. The semiconductor device array of claim 1, wherein the first spacer and the second spacer have a thickness between five and twenty nanometers (nm).

13. The semiconductor device array of claim 1, wherein:
a third transistor is surrounded by a third spacer and a third additional spacer; and
the third transistor is not in contact with the backside-connecting via.

14. The semiconductor device of claim 1, wherein the first transistor and the second transistor are selected from a group consisting of a fin field effect transistor (FinFET), a vertical transport FET (VTFET), a semiconductor memory structure, and combinations thereof.

15. A semiconductor device array comprising:
a backside power distribution network (BSPDN);
a buried power rail (BPR) in contact with the BSPDN;
a device layer comprising:
a first transistor;
a second transistor;
a first spacer; and
a second spacer, wherein:
the first transistor is in contact with the first spacer;
the second transistor is in contact with the second spacer;
the first spacer neighbors the second spacer; and
the first transistor neighbors the second transistor; and
a backside-connecting via that is in contact with the first transistor, the BPR, the first spacer, and the second spacer, wherein:
the second spacer prevents a short resulting from electrical contact between the second transistor and the backside-connecting via;
the backside-connecting via is in electrical contact with a top surface of the first transistor;
the first spacer and a first additional spacer surround the first transistor; and
the second spacer and a second additional spacer surround the second transistor.

16. A method for fabricating a semiconductor device, the method comprising:
depositing a dielectric layer over a plurality of transistors;
performing a directional reactive ion etch-back of the dielectric layer to form a plurality of spacers that surround each of the plurality of transistors; and
forming a backside-connecting via between two of the plurality of transistors, wherein the backside-connecting via provides a current path between a buried power rail (BPR) and a first transistor of the plurality of transistors.

17. The method of claim 16, wherein forming the backside-connecting via comprises forming the backside-connecting via without metal voids.

18. The method of claim 16, further comprising:
forming a device layer comprising the first transistor, a second transistor, a first spacer, and a second spacer, wherein:
the first transistor is in contact with the first spacer;
the second transistor is in contact with the second spacer; and
the first transistor neighbors the second transistor;
forming the backside-connecting via in contact with the first transistor and a backside power distribution network (BSPDN).

19. The method of claim 18, wherein the second spacer prevents a short between the backside-connecting via and the second transistor.

20. The method of claim 16, the plurality of transistors are selected from a group consisting of a fin field effect transistor (FinFET), a vertical transport FET (VTFET), a semiconductor memory structure, and combinations thereof.
